(19) United States
(12) Patent Application Publication
(10) Pub. No.: US 2025/0132201 A1
(43) Pub. Date: Apr. 24, 2025

(54) NUCLEATION-FREE DEPOSITION

(71) Applicant: Lam Research Corporation, Fremont, CA (US)

(72) Inventors: Sema ERMEZ, Santa Clara, CA (US); Ruopeng DENG, San Jose, CA (US); Yutaka NISHIOKA, Saijo-cho (JP); Xiaolan BA, Fremont, CA (US); Sanjay GOPINATH, Fremont, CA (US); Michal DANEK, Cupertino, CA (US)

(21) Appl. No.: 19/000,548

(22) Filed: Dec. 23, 2024

Related U.S. Application Data
(63) Continuation of application No. 17/595,590, filed on Nov. 19, 2021, now Pat. No. 12,237,221.
(60) Provisional application No. 62/851,552, filed on May 22, 2019.

(51) Int. Cl. H01L 21/768; C23C 16/08; C23C 16/455; H01L 21/285

(52) U.S. Cl. CPC H01L 21/76876; C23C 16/08; C23C 16/45525; H01L 21/28568

(57) ABSTRACT

Provided herein are methods of depositing tungsten (W) films without depositing a nucleation layer. In certain embodiments, the methods involve depositing a conformal reducing agent layer of boron (B) and/or silicon (Si) on a substrate. The substrate generally includes a feature to be filled with tungsten with the reducing agent layer conformal to the topography of the substrate including the feature. The reducing agent layer is then exposed to a fluorine-containing tungsten precursor, which is reduced by the reducing agent layer to form a layer of elemental tungsten. The conformal reducing agent layer is converted to a conformal tungsten layer.

### INCORPORATION BY REFERENCE

An Application Data Sheet is filed concurrently with this specification as part of the present application. Each application that the present application claims benefit of or priority to as identified in the concurrently filed Application Data Sheet is incorporated by reference herein in their entireties and for all purposes.

### BACKGROUND

Deposition of conductive materials such as tungsten films is an integral part of many semiconductor fabrication processes. These materials may be used for horizontal interconnects, vias between adjacent metal layers, contacts between metal layers and devices on the silicon substrate, and high aspect ratio features. As devices shrink and more complex patterning schemes are utilized in the industry, deposition of thin tungsten films becomes a challenge. These challenges include depositing low resistivity films having good step coverage.

The background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

Provided herein are methods for forming tungsten bulk layers. One aspect of the disclosure relates to a method including depositing a tungsten bulk layer without depositing a tungsten nucleation layer on a surface of a substrate by forming a layer including elemental boron (B) on the surface; and after forming the layer, performing multiple cycles of exposing the substrate to alternating pulses of a tungsten fluoride compound and hydrogen (H₂) to thereby form an elemental tungsten bulk layer on the surface. In some embodiments, the layer including elemental boron is between 10 and 50 Angstroms thick. In some embodiments, the B content at the interface of the elemental tungsten bulk layer and the surface is no more than 10²¹ atoms/cm³. In some embodiments, the B content is no more than 5×10²⁰ atoms/cm². In some embodiments, the B content is no more than 2×10²⁰ atoms/cm².

In some embodiments, the layer including elemental boron consists essentially of boron. In some embodiments, the layer including elemental boron further includes silicon. In some embodiments, the layer consists essentially of boron and silicon.

In some embodiments, the surface is a nitride surface, with examples including a titanium nitride (TiN) surface. In some embodiments, the surface is an oxide surface.

In some embodiments, forming the layer including elemental boron involves exposing the surface to diborane. Example exposure times may range from 30 to 120 seconds. In some embodiments, forming the layer including elemental boron involves exposing the surface to diborane and silane.

In some embodiments, a chamber pressure of a chamber housing the substrate during formation of the layer comprising elemental boron is between 10 Torr and 90 Torr.

In some embodiments, the operations of forming the layer comprising elemental boron and performing multiple cycles are performed in the same chamber. In some embodiments, the method further involves lowering the chamber pressure after forming the layer comprising elemental boron and prior to performing the multiple cycles.

In some embodiments, forming a layer comprising elemental boron (B) on the surface includes exposing the surface to a gas mixture comprising boron (B) and silicon (Si) wherein the B:Si ratio is between 1:1 and 6:1. In some embodiments, the gas mixture includes diborane and silane.

In some embodiments, forming a layer comprising elemental boron (B) on the surface involves thermal decomposition of a boron-containing reducing agent without adsorption of the boron-containing reducing agent on the surface. In some embodiments, the layer of elemental boron conforms to the surface topography.

Apparatuses to perform the methods are also provided. These and other aspects of the disclosure are discussed further below with reference to the drawings.

### BRIEF DESCRIPTION OF DRAWINGS

FIGS. 1A and 1B depict example metal stacks that include bulk tungsten.

FIG. 2 depicts a schematic example of a buried wordline (bWL) structure that includes tungsten.

FIGS. 3A depicts a schematic example of tungsten wordlines in a 3D NAND structure.

FIG. 3B depicts a detail of the interface between a tungsten wordline and an oxide layer in a 3D NAND structure.

FIG. 3C depicts a schematic cross-sectional side view of a partially fabricated 3-D NAND structure.

FIG. 3D depicts a schematic top view of a partially fabricated 3-D NAND structure.

FIG. 4 is a process flow diagram illustrating operations of a method of depositing a bulk tungsten layer without a nucleation layer.

FIGS. 5A-5D show examples of pulsed flow sequences of reducing agents that may be used to deposit boron (B) or boron(silicon) (B(Si)) layers.

FIG. 6 shows an example of a pulsed flow sequence of a tungsten precursor that may be used to convert a B or B(Si) layer.

FIG. 7A is a process flow diagram illustrating operations of a method of depositing a bulk tungsten layer without a nucleation layer.

FIG. 7B shows the atomic concentrations of boron and fluorine as a function of depth in a SiOx/TiN/W stack for W films deposited with and without nucleation layers.

FIGS. 8A-8J are schematic diagrams of an example of a mechanism for depositing films in accordance with disclosed embodiments.

FIG. 9 is a schematic diagram of an example process tool for performing disclosed embodiments.

FIG. 10 is a schematic diagram of an example station for performing disclosed embodiments.

### DETAILED DESCRIPTION

Provided herein are methods and apparatuses for forming metal films such as tungsten (W) films on semiconductor substrates. The methods involve forming a sacrificial layer of a silicon (Si) and/or boron (B) prior to deposition of a bulk layer of the metal on the substrate. The sacrificial layer reacts with a metal precursor to form part of the bulk layer. In this manner, tungsten can be deposited directly on surfaces such as diffusion barrier or dielectric surfaces without deposition of a nucleation layer. Apparatuses to perform the methods are also provided.

Forming electrical contacts or lines in semiconductor device fabrication can involve filling features with tungsten or other electrically conductive materials. A nucleation layer can first be deposited into a via or contact. A nucleation layer is a thin conformal layer that serves to facilitate the subsequent formation of a bulk material thereon. A tungsten nucleation layer may be deposited to conformally coat the sidewalls and, if present, bottom of the feature. After the tungsten nucleation layer is deposited, bulk tungsten may be deposited on the tungsten nucleation layer. Unlike a nucleation layer, which is a thin conformal film that serves to facilitate the subsequent formation of a bulk material thereon, bulk tungsten is used to carry current. Bulk tungsten is compositionally distinct from a tungsten nucleation layer such that there is an interface between the bulk tungsten and nucleation layer. In some cases, nucleation layers have relatively high amorphous and/or beta phase content, while bulk layers have high alpha phase content. Bulk tungsten also has large grain size and lower resistivity than a nucleation layer.

There are various challenges in tungsten fill as devices scale to smaller technology nodes and more complex patterning structures are used. One challenge is distribution of material with a structure. Distribution of a material within a feature may be characterized by its step coverage. For the purposes of this description, “step coverage” is defined as a ratio of two thicknesses-the thickness of the material inside the feature divided by the thickness of the material near the opening. For purposes of this document, the term “inside the feature” represents a middle portion of the feature located about the middle point of the feature along the feature's axis, e.g., an area between about 25% and 75% of the distance or, in certain embodiments, between about 40% and 60% of the distance along the feature's depth measured from the feature's opening, or an end portion of the feature located between about 75% and 95% of the distance along the feature's axis as measured from the opening. The term “near the opening of the feature” or “near the feature's opening” represents a top portion of the feature located within 25% or, more specifically, within 10% of the opening's edge or other element representative of the opening's edge. Step coverage of over 100% can be achieved, for example, by filling a feature wider in the middle or near the bottom of the feature than at the feature opening.

Another challenge is reducing resistance in the deposited tungsten films. Thinner films tend to have higher resistance than thicker films. As features become smaller, the tungsten contact or line resistance increases due to scattering effects in the thinner tungsten films. Low resistivity tungsten films minimize power losses and overheating in integrated circuit designs. Tungsten nucleation layers typically have higher electrical resistivities than the overlying bulk layers. Further, tungsten nucleation films occupy a larger percentage of smaller features, increasing the overall resistance in the feature. Resistivity of a tungsten film depends on the thickness of the film deposited, such that resistivity increases as thickness decreases due to boundary effects.

Another challenge is reducing stress on deposited films. Thinner tungsten films tend to have increased tensile stress. Depositing bulk tungsten films by chemical vapor deposition can result in a tensile stress greater than 2.5 GPa for a 200 Å film. High thermal tensile stress causes the substrate to curl, which makes subsequent processing difficult. For example, subsequent processes may include chemical mechanical planarization, deposition of materials, and/or clamping of the substrate to a substrate holder to perform processes in a chamber. However, these processes often rely on the substrate being flat, and a curled substrate results in nonuniform processing or inability to process the substrate. Although there are existing methods for reducing stress in films of other materials such as annealing, tungsten does not have the surface mobility to allow grains to be moved or altered once it is deposited due to its high melting point.

One aspect of the disclosure relates to methods of depositing tungsten films without depositing a nucleation layer. In certain embodiments, the methods involve depositing a conformal reducing agent layer of silicon (Si) and/or boron (B) on a substrate. The substrate generally includes a feature to be filled with tungsten as described above, with the reducing agent layer conformal to the topography of the substrate including the feature. The reducing agent layer is then exposed to a fluorine-containing tungsten precursor, which is reduced by the reducing agent layer to form a layer of elemental tungsten. The conformal reducing agent layer is converted to a conformal tungsten layer. According to various embodiments, the fluorine-containing tungsten precursor may or may not be provided in the presence of hydrogen (H₂) gas.

According to various embodiments, one or more of the following advantages may be realized using the methods described herein. Tungsten films deposited using the nucleation- free methods described herein can have lower resistivity than tungsten films deposited on nucleation layers. Tungsten films deposited using the nucleation-free methods described herein can have lower B, Si, or B and Si concentration than tungsten films deposited on nucleation layers formed using boron-containing and/or silicon-containing reducing agents. Tungsten films deposited using the nucleation-free methods described herein can have large grain size without a grain boundary at nucleation-bulk interface. In some embodiments, grain size and orientation can be controlled by the amount of B or B and Si in the reducing agent layer. In some embodiments, higher throughput may be achieved due to not forming a nucleation layer.

In some embodiments, the conversion described above occurs as part of a bulk tungsten deposition process. The bulk tungsten deposition process may use H₂ as a reducing agent and grow tungsten bulk film from the substrate surface on which the Si and/or B layer was previously deposited. Unlike a bulk film deposited on a nucleation layer, the resulting tungsten film stack has no nucleation layer/bulk layer interface.

In some embodiments, if the conformal reducing agent layer is the only available reducing agent for the fluorine-containing tungsten precursor, excess precursor may be used to ensure complete conversion to tungsten. The conversion is self-limiting, with its step coverage defined by the step coverage of the reducing agent layer.

In some embodiments, the reducing agent layer and the subsequent tungsten layer is formed directly on an oxide surface, such as a silicon oxide (e.g., SiO₂) or aluminum oxide (e.g., Al₂O₃) surface. This eliminates the need for an adhesion/barrier layer such as a titanium nitride (TiN) layer or titanium/titanium nitride (Ti/TiN) bilayer.

Methods described herein are performed on a substrate that may be housed in a chamber. The substrate may be a silicon wafer, e.g., a 200-mm wafer, a 300-mm wafer, or a 450-mm wafer, including wafers having one or more layers of material, such as dielectric, conducting, or semi-conducting material deposited thereon.

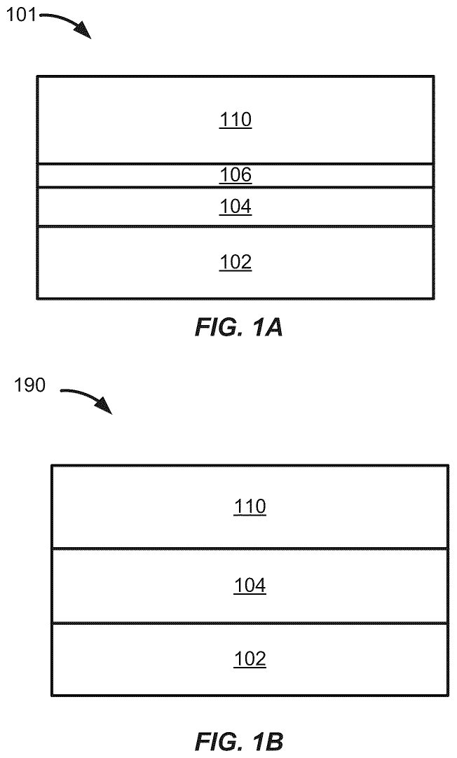

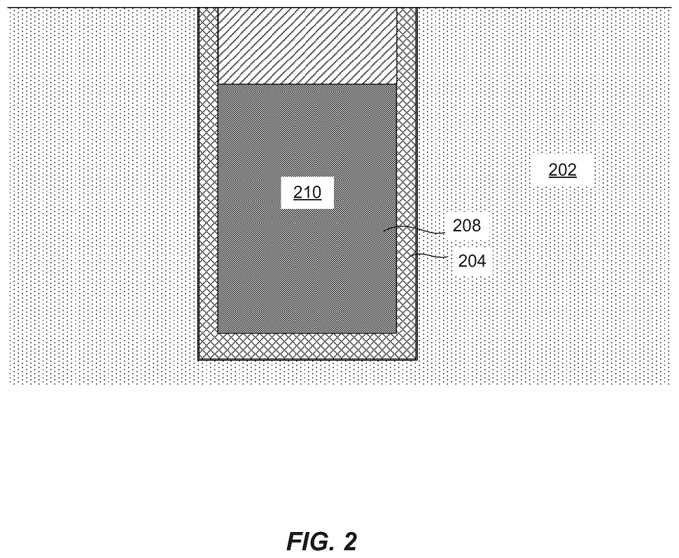

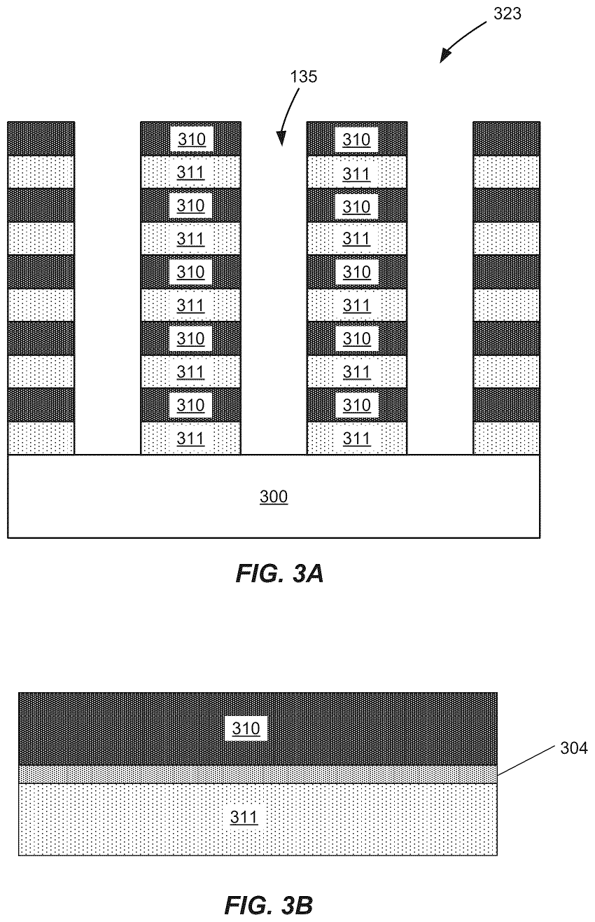

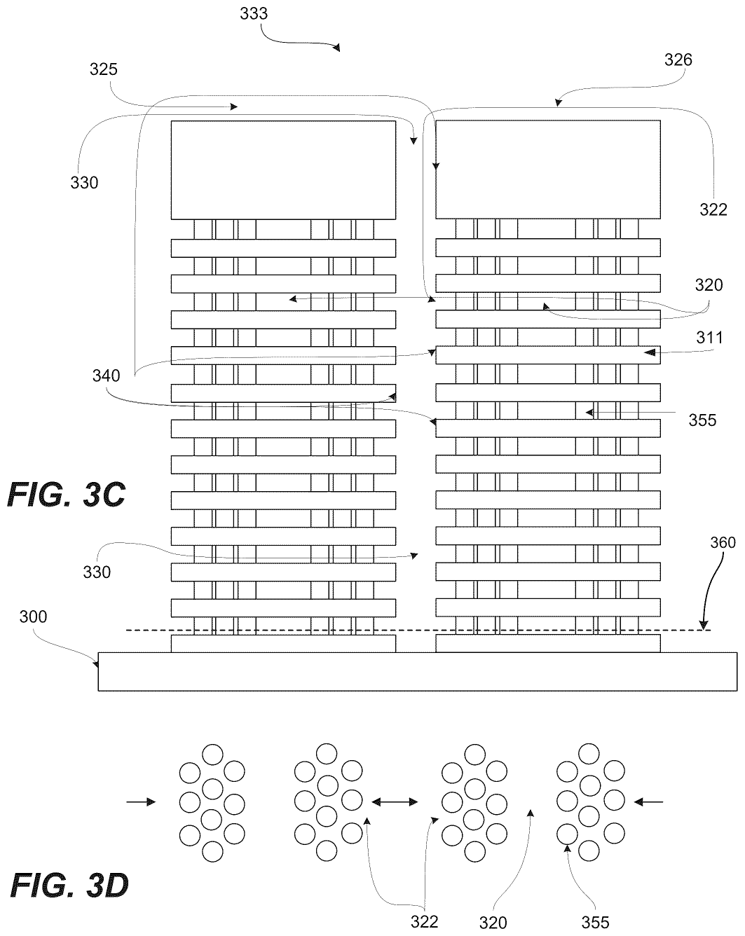

FIGS. 1A and 1B are schematic examples of material stacks that include a bulk tungsten layer directly contacting on an underlying layer without an intervening nucleation layer. FIGS. 1A and 1B illustrate the order of materials in a particular stack and may be used with any appropriate architecture and application, as described further below with respect to FIGS. 2, 3A, and 3B. In the example of FIG. 1A, a substrate 102 has a nucleation layer 108 deposited thereon. The substrate 102 may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. The methods may also be applied to form metallization stack structures on other substrates, such as glass, plastic, and the like.

In FIG. 1A, a dielectric layer 104 is on the substrate 102. The dielectric layer 104 may be deposited directly on a semiconductor (e.g., Si) surface of the substrate 102, or there may be any number of intervening layers. Examples of dielectric layers include doped and undoped silicon oxide, silicon nitride, and aluminum oxide layers, with specific examples including doped or undoped layers SiO₂ and Al₂O₃. Also, in FIG. 1A, a diffusion barrier layer 106 is disposed between and the dielectric layer 104 and a bulk tungsten layer 110. Examples of diffusion barrier layers including titanium nitride (TiN), titanium/titanium nitride (Ti/TiN), tungsten nitride (WN), and tungsten carbon nitride (WCN). The bulk tungsten layer 110 is deposited on the diffusion barrier layer 106 and is the main conductor (also referred to as a bulk conductor or bulk layer) of the structure.

FIG. 1B shows another example of a material stack 190. In this example, the stack includes the substrate 102, dielectric layer 104, with the nucleation layer 108 deposited directly on the dielectric layer 104, without an intervening diffusion barrier layer. As in the example of FIG. 1A, a bulk tungsten layer 110 is deposited on the nucleation layer 108 and is the main conductor of the structure.

While FIGS. 1A and 1B show examples of metallization stacks, the methods and resulting stacks are not so limited and include any tungsten having a tungsten bulk layer. The methods described herein are performed on a substrate that may be housed in a chamber.

The material stacks described above and further below may be implemented in a variety of structures. FIGS. 2, 3A, and 3B provide examples of structures in which the stacks may be employed. FIG. 2 depicts a schematic example of a DRAM architecture including a buried wordline (bWL) 210 in a silicon substrate 202. The bWL 210 is formed in a trench etched in the silicon substrate 202. Lining the trench is an insulating layer 204 that is disposed between the bWL 210 and the silicon substrate 202. In the example of FIG. 2, the insulating layer 204 may be a gate oxide layer, formed from a high-k dielectric material such as a silicon oxide or silicon nitride material. In some embodiments, a conformal barrier layer such as TiN or a tungsten-containing layer may be interposed between the bWL 210 and the insulating layer 204.

FIG. 3A depicts a schematic example of wordlines 310 in a 3D NAND structure 323 formed on a substrate 300. The wordlines 310 are separated by oxide layers 311. In FIG. 3B, a detail of the interface between a wordline 310 and oxide layer 311 is shown with a layer of TiN 304. In some embodiments, bulk tungsten of the tungsten wordline 310 may be deposited directly on the oxide layer 311 (or layer of aluminum oxide if present) or on a TiN or other barrier layer as described herein. Example thicknesses of wordline 310 may be between about 10 nm and 100 nm thick.

FIG. 3C presents a cross-sectional side view of a partially fabricated 3-D NAND structure 333 and illustrates challenges of metal fill. The structure 330 is formed on a semiconductor substrate 300 and includes 3D NAND stacks (left 325 and right 326), central vertical structure 330, and a plurality of stacked wordline features 320 with openings 322 on opposite sidewalls 340 of central vertical structure 330. Note that FIG. 3C displays two stacks 325 and 326 of the exhibited partially fabricated 3-D NAND structure 333, which together form the trench-like central vertical structure 330, however, in certain embodiments, there may be more than two stacks arranged in sequence and running spatially parallel to one another, the gap between each adjacent pair of stacks forming a central vertical structure 330, like that explicitly illustrated in FIG. 3C. In the example of FIG. 3C, the wordline features 320 are fluidically accessible from the central vertical structure 330 through the openings 322. Although not explicitly indicated in the figure, the horizontal features 320 present in both the 3-D NAND stacks 325 and 326 shown in FIG. 3C (i.e., the left 3-D NAND stack 325 and the right 3-D NAND stack 326) are also accessible from the other sides of the stacks (far left and far right, respectively) through similar vertical structures formed by additional 3-D NAND stacks (to the far left and far right, but not shown). In other words, each 3-D NAND stack 325, 326 contains a stack of wordline features that are fluidically accessible from both sides of the 3-D NAND stack through a central vertical structure 330.

The wordline features in a 3-D NAND stack may be formed by depositing an alternating stack of silicon oxide and silicon nitride layers, and then selectively removing the nitride layers leaving a stack of oxide layers 311 having gaps between them. These gaps are the wordline features 320. Any number of wordlines may be vertically stacked in such a 3-D NAND structure so long as there is a technique for forming them available, as well as a technique available to successfully accomplish substantially void-free fills of the vertical features. Thus, for example, a 3D-NAND stack may include between 2 and 256 horizontal wordline features, or between 8 and 128 horizontal wordline features, or between 16 and 64 horizontal wordline features, and so forth (the listed ranges understood to include the recited end points).

FIG. 3D presents a cross-sectional top-down view of the same 3-D NAND structure shown in FIG. 3C with the cross-section taken through the horizontal section 360 as indicated by the dashed horizontal line in FIG. 3C. The cross-section of FIG. 3C illustrates several rows of pillars 355, which are run vertically from the base of semiconductor substrate 300 to the top of the 3-D NAND stacks. In some embodiments, these pillars 355 are formed from a polysilicon material and are structurally and functionally significant to the 3-D NAND structure 333. In some embodiments, such polysilicon pillars may serve as gate electrodes for stacked memory cells formed within the pillars. The top-view of FIG. 3D illustrates that the pillars 355 form constrictions in the openings 322 to wordline features 320—i.e. fluidic accessibility of wordline features 320 from the central vertical structure 330 via openings 322 (as indicated by the arrows in FIG. 3D) is inhibited by pillars 355. In some embodiments, the size of the horizontal gap between adjacent polysilicon pillars is between about 1 and 20 nm. This reduction in fluidic accessibility increases the difficulty of uniformly filling wordline features 320 with conductive material.

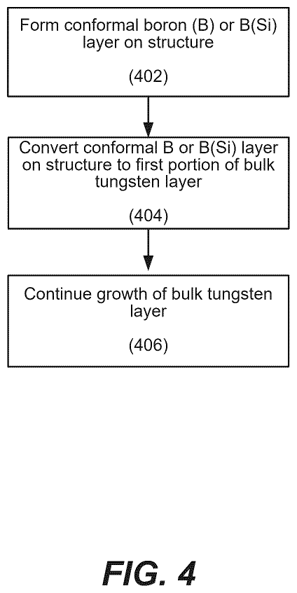

FIG. 4 is a process flow diagram of a method performed in accordance with disclosed embodiments. Operations 402-408 may be performed to deposit a bulk tungsten layer on a structure without first depositing a nucleation layer. That is, these operations are formed without prior deposition of a nucleation layer. Prior to operation 402, a substrate having a structure with one or more features to be filled without a nucleation layer may be provided to a process chamber. In some embodiments, the surface on which the bulk tungsten layer is deposited is a barrier layer such as a titanium nitride (TiN) or tungsten carbon nitride (WCN) layer. In some embodiments, the surface on which the bulk tungsten layer is deposited in an oxide or other dielectric layer.

As described below, certain operations are performed at substrate temperatures. It will be understood that substrate temperature refers to a temperature to which the pedestal holding the substrate is set.

In operation 402, a layer of boron (B) or boron and silicon (denoted B(Si)) is formed on the structure. The layer is conformal in that it conforms to the shape of the structure to be filled with a tungsten bulk layer. To form the conformal layer, the structure is exposed to a boron-containing gas and/or a silicon-containing gas. Examples of boron-containing gases include boranes and examples of silicon-containing gases include silanes. Examples of boranes include diborane (B₂H₆), as well as BₙHₙ₊₄, BₙHₙ₊₆, BₙHₙ₊₈, BₙHₘ, where n is an integer from 1 to 10, and m is a different integer than m. Other boron-containing compounds may also be used, e.g., alkyl boranes, alkyl boron, aminoboranes (CH₃)₂NB(CH₂)₂, carboranes such as C₂BₙHₙ₊₂. Examples of silanes including SiH₄ and Si₂H₆. While other gases may be used, boranes and silanes may advantageously used to have a layer of B and/or Si without impurities.

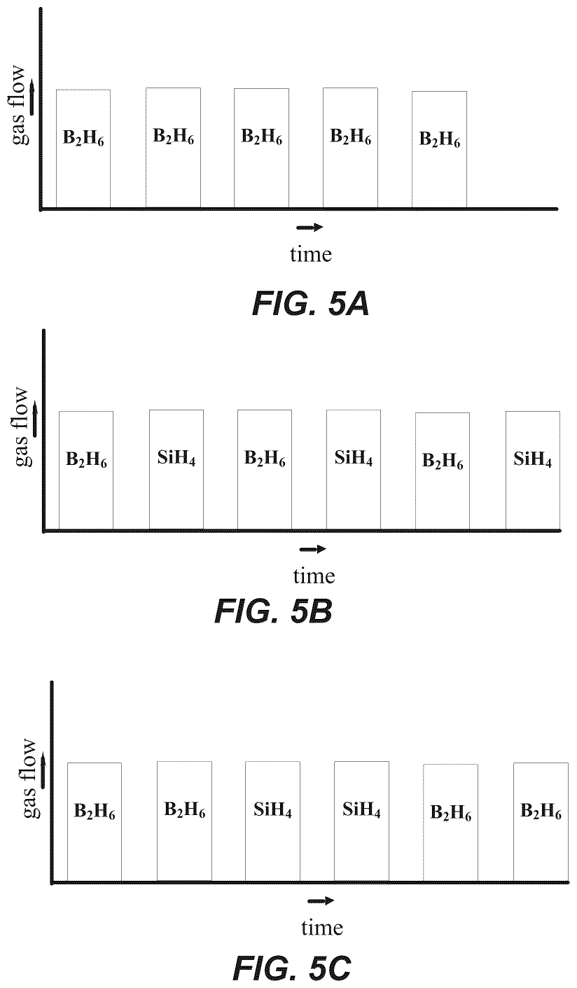

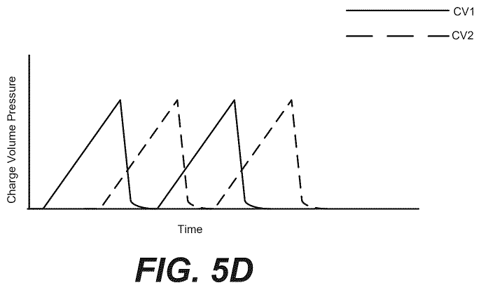

In some embodiments, a carrier gas may be flowed during operation 402. In some embodiments, a carrier gas, such as nitrogen (N₂), argon (Ar), helium (He), or other inert gases, may be flowed during operation 402. As described further below with respect to FIGS. 5A-5D, operation 402 may involve one or multiple pulses of the gases.

When exposing a surface to a borane, the borane may thermally decompose to form a layer of elemental boron (B) or the borane may be adsorbed onto the substrate. To form a layer of boron on the structure, it is exposed to a borane or other boron-containing gases using conditions under which thermal decomposition will occur. This is in contrast to nucleation layer deposition in which adsorption may be favored.

Nucleation layer deposition may involve sequential alternating pulses of a boron-containing reducing agent and tungsten-containing precursor separated by purges. The pulses are relatively short. Conditions that favor adsorption may be used at least because thermal decomposition using short pulses can lead to poor step coverage over complex structures such as 3D NAND structures. Further, during nucleation layer deposition, relatively low chamber pressures may be used to reduce fluorine incorporation when using a fluorine-containing precursor.

To favor thermal decomposition over adsorption, temperature may be controlled. The substrate temperature at block 402 is thus higher than the decomposition point at that pressure. For diborane, for example, a temperature of 250° C.-400° C. may be used at 40 Torr. Lower temperatures (e.g., 225° C.) may be used for some compounds and conditions. It should also be known that temperatures on the higher end of the range may be harder to control. As such, for diborane, a range of 250° C.-350° C., or 250° C.-300° C. may be used. Example chamber pressures may be between 10 Torr and 90 Torr, or 10 Torr and 50 Torr. Higher pressures can improve step coverage in some embodiments. Pressure during operation 402 may be higher than generally used for nucleation layer deposition. Hydrogen (H₂) may or may not be present; the addition of H₂ can slow down the formation of the conformal layer. In some embodiments, operation 402 is performed without a purge during operation 402. This also enables higher pressures to be used in some embodiments with purges being more difficult at higher pressures. Thermal decomposition may also be favored by using longer pulse times and/or higher flow rates than used for nucleation layer deposition. Temperature during operation 402 may be higher than generally used for nucleation layer deposition.

In some embodiments, SiH₄, or other silane or silicon-containing compound is also used in operation 402 with elemental silicon (Si) also incorporated into the conformal layer. Thermal decomposition of silane on its own is more difficult than that of diborane; however, using silane with diborane has been found to increase deposition rate of the conformal layer. A volumetric flow rate ratio of 1:1 B₂H₆:SiH₄ was found to provide the fastest deposition rate at 300°° C. and 10 Torr; with up to 3:1 also providing good deposition rates. Having more silane than diborane results in reduced deposition rate, with the reduction increasing as the silane content increases. The B:S ratio (flow rates into the chamber as well as in the layer) may be 1:1-6:1 in some embodiments. Volumetric flow rates of B₂H₆:SiH₄ may be 0.5:1-3:1.

Using both a boron-containing compound and a silicon-containing compound forms a layer including B and Si. It is possible that some amount of adsorbed silane is present in the layer. Also in some embodiments, silane or other silicon-containing compound only may be used in operation 402. However, as indicated above, deposition rate is much slower and decomposition is more difficult.

Still further, in some other embodiments, the conformal layer may include elemental elemental germanium (Ge) alone or with other constituents. For any of the layers described above, the layers may consist essentially of the elemental reducing agent or mixtures of elemental reducing agents (e.g., B, B(Si), Si, etc.) or other atoms may be present. For example, SiHₓ, BH_{y}, GeH_{z}, or mixtures thereof where x, y, and z may independently be between 0 and a number that is less than the stoichiometric equivalent of the corresponding reducing agent compound may be present. A layer that consists essentially of a reducing agent will have no more than trace amounts of other atoms.

Example thicknesses of the conformal B or B(Si) layer are 1-5 nm. In some embodiments, the thickness is below 3 nm. If the layer is too thick, it may not all be converted to tungsten; too thin, and it may not result in uniform and continuous film growth.

Operation 402 may be performed using continuous flow or pulses of the one or more reducing agents. FIGS. 5A-5D, described further below, show examples of pulsed flow sequences.

In operation 404, the conformal B or B(Si) (or other conformal layer as described above) is converted to a first portion of a bulk tungsten layer. Operation 404 involves exposing the conformal B or B(Si) layer to a tungsten-containing precursor, typically a fluoride-containing tungsten precursor such as WF₆. Operation 404 may involve one or more WF₆ pulses or WF₆ and H₂ pulses. Operation 404 generally continues until the B or B(Si) layer is fully converted. The result in a layer of elemental tungsten (W). An example reaction is:

WF₆ (g)+2B (s)→W (s)+2BF₃ (g)

In some embodiments, pressure during operation 404 is below 20 Torr, e.g., 10 Torr, or below 10 Torr. In some embodiments, a carrier gas, such as argon (Ar), helium (He), or other inert gases, may be flowed during operation 404. In various embodiments, during operation 404, the amount of precursor by volume may be between about 2% and about 10%.

Once the B or B(Si) layer is converted, growth of the bulk tungsten layer is continued in an operation 406. As discussed further below, this operation can involve ALD deposition of bulk tungsten using H₂ a reducing agent. Thus, in some embodiments, after operation 402, repeated cycles of an ALD sequence a tungsten-containing precursor and H₂ (e.g., WF₆/purge/H₂/purge) are performed to initiate and complete operations 404 and 406.

To deposit a B layer, diborane or other boron-containing reducing agent is flowed into the deposition chamber. This may be done as a continuous flow or in pulses (see, e.g., FIG. 5A). Hydrogen or other carrier gas may or may not be present. Diborane or other boron-containing reducing gas may be provided in dilute form, e.g., 5% diborane by volume with the balance nitrogen (N₂) gas. As noted above, example substrate temperatures 250° C.-300° C. and chamber pressures of 10-90 Torr may be used. To deposit a B(Si) layer, higher substrate temperatures, e.g., 250° C.-400° C. may be used. Chamber pressures of 10-90 Torr may also be used for B(Si) layers. In addition to a boron-containing reducing agent, a silicon-containing reducing agent is flowed in the deposition chamber. This may take the form of sequential single B-containing reducing agent and Si-containing reducing agent pulses (see FIG. 5B) or sequential multiple single B-containing reducing agent and Si-containing reducing agent pulses (see FIG. 5C). In some embodiments, the B-containing and Si-containing reducing agents are co-flowed into the deposition chamber, either in a continuous flow or in pulses.

FIG. 5A-5C depict intervals between pulses; purging in the intervals can be but is often not employed in these intervals. In some embodiments, the pulses may overlap. In some embodiments, multiple charge volumes may be used to deliver reducing agent pulses. A charge volume is a container in which a gas accumulates at a charge volume pressure. FIG. 5D shows an example of pressure of two charge volumes (CV1 and CV2) delivering sequential pulses. Each charge volume may contain the same (e.g., B₂H₆) or different (B₂H₆ and SiH₄) reducing agents. Use of a charge volume and especially multiple charge volumes can aid in step coverage throughout a structure. In some embodiments, the discharges may overlap.

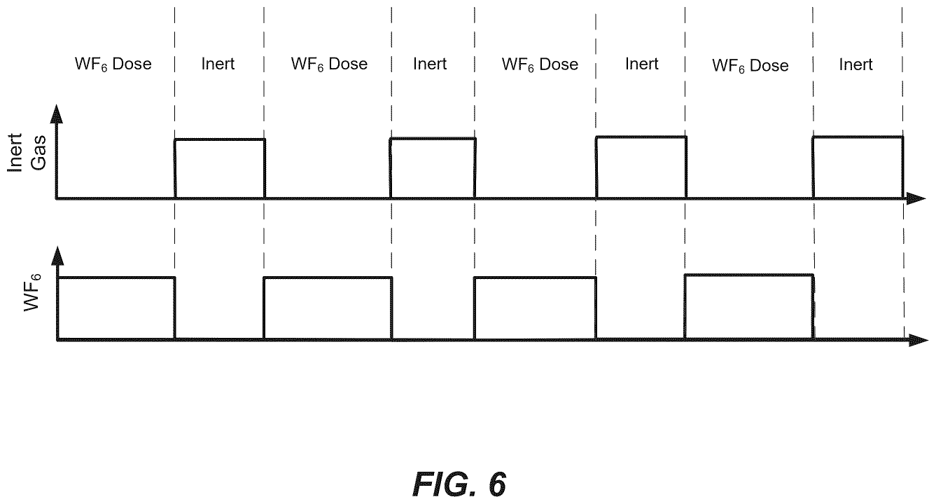

As indicated above, to convert the B or B(Si) layer, the substrate is exposed to a tungsten-containing precursor. This may be performed with continuous or pulsed flow. FIG. 6 provides an example of pulsed flow.

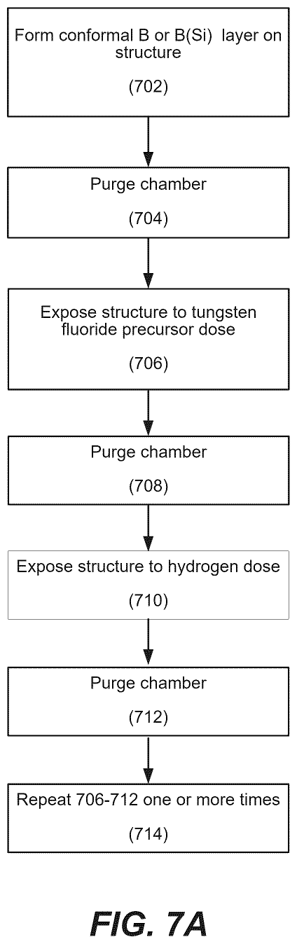

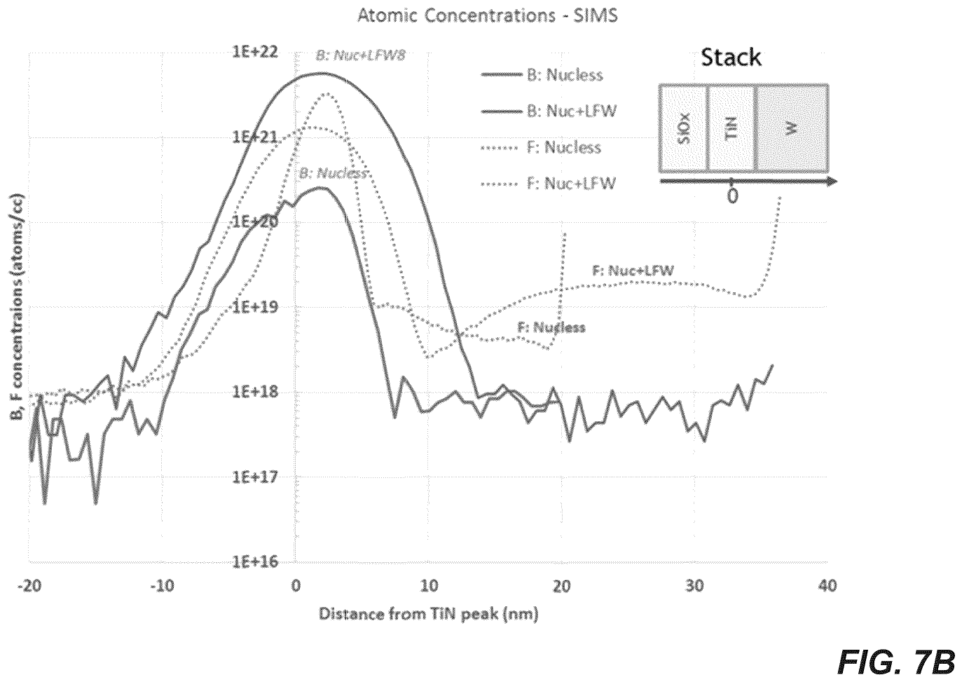

Also provided herein are methods of depositing a bulk tungsten film without depositing a nucleation layer. FIG. 7A provides a process flow diagram illustrating operations in depositing a tungsten bulk layer. First, at operation 702, a conformal B or B(Si) layer is formed on a structure. This may be performed as discussed above with respect to operation 402 of FIG. 7A. In some embodiments, the conformal layer is formed on a nitride barrier layer. In an operation 704, the chamber in which the structure resides may be purged to remove vapor phase reducing agent used to form the conformal layer. Next the structure is exposed to a dose of a tungsten fluoride precursor. (706). In other embodiments, a tungsten chloride precursor may be used. The chamber is purged in an operation 708. The structure is then exposed to a hydrogen (H₂) dose at operation 710, followed by a purge at operation 712. Operations 706-712 may be repeated one or more times (714).

In some embodiments, pressure during at least operations 706-712 is relatively low, and can be no more than 40 Torr or no more than 20 Torr. In some embodiments, it is between 5 Torr and 20 Torr, or between 7 and 13 Torr. In a specific example, the pressure is about 10 Torr. In some embodiments, pressure is reduced between operation 702 and operation 706.

That is, the B or B(Si) layer may be formed using a high pressure with subsequent operations using a lower pressure. In this manner, a low fluorine tungsten bulk layer is deposited.

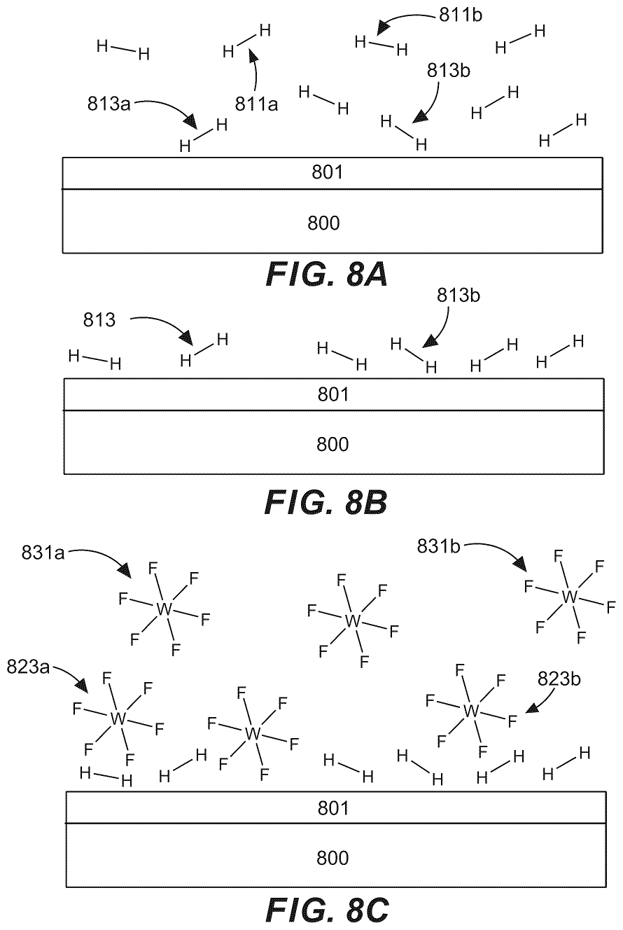

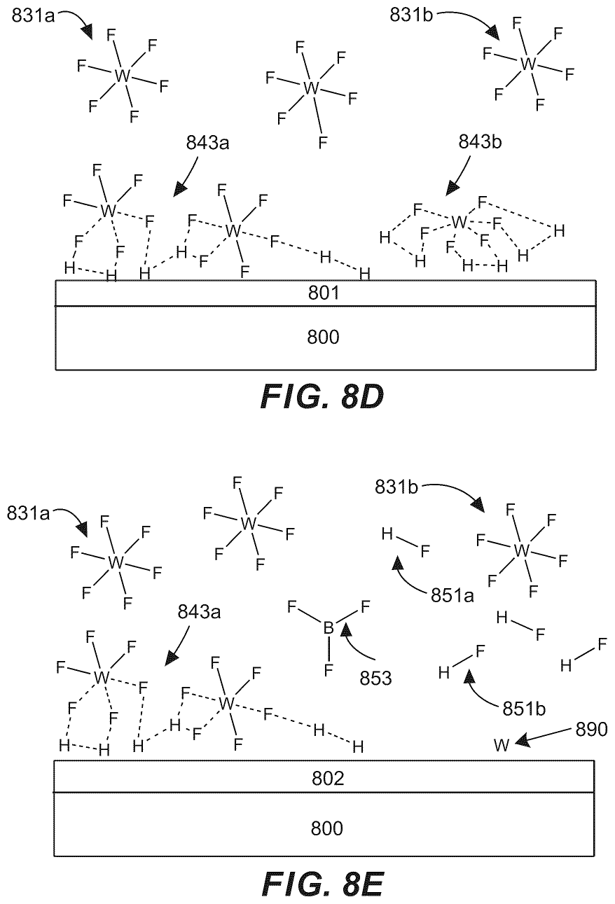

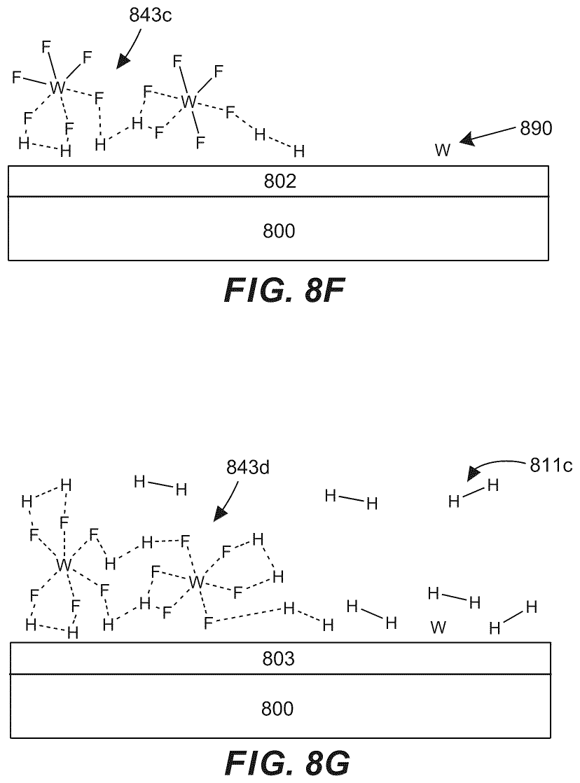

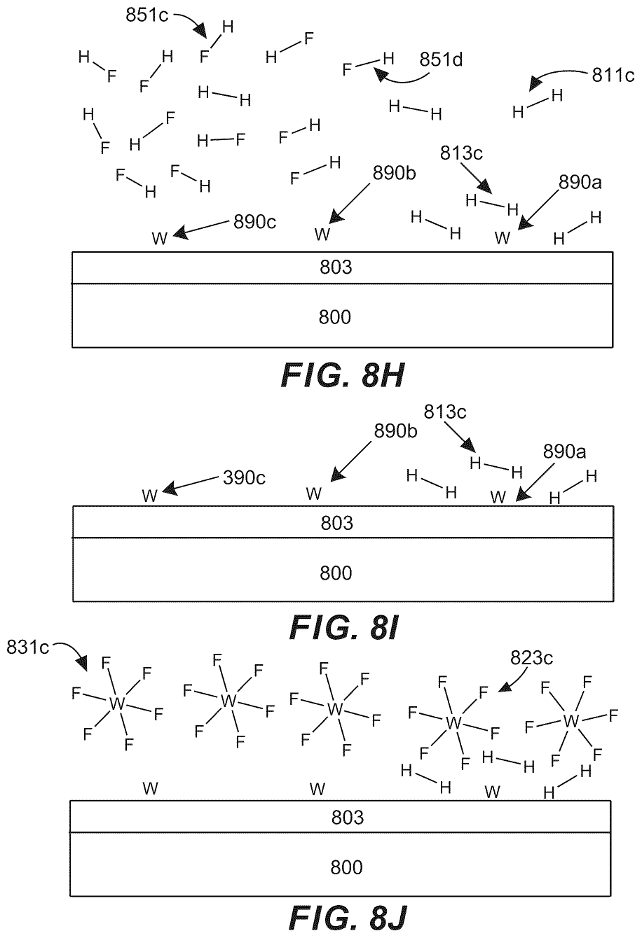

FIGS. 8A-8J are schematic illustrations of an example mechanism of a deposition cycle. FIG. 8A depicts an example mechanism where a substrate including a TiN layer 800 and a reducing agent layer 801 (e.g., B or B(Si) layer) is exposed to H₂. Hydrogen is introduced in gas phase (811a and 811b) and some H₂ (813a and 813b) is on the surface of the B or B(Si) layer 801, where it may dissociate into chemically active adsorbed atomic hydrogen or physisorb. For example, H₂ may not necessarily chemisorb onto the 401, but in some embodiments, may physisorb onto the surface of the reducing agent layer 801. This can form a solid Si—B—H interfacial surface layer.

FIG. 8B shows an example illustration whereby H₂ previously in gas phase (811a and 811b in FIG. 8A) are purged from the chamber, and H₂ previously on the surface (843a and 813b) remain on the surface of the reducing agent 801.

FIG. 8C shows an example schematic illustration whereby the substrate is exposed to WF₆, some of which is in gas phase (831a and 831b) and some of which is at or near the surface of the substrate (823a and 823b).

Some H₂ may react with WF₆ that remained on the surface from the prior dose. In FIG. 8D, WF₆ may react with H₂ to temporarily form intermediate 843b, whereby in FIG. 8E, intermediate 843b fully reacts to form tungsten 890 and HF in gas phase (851a and 851b, for example). WF₆ or an intermediate may also react with B in the reducing agent layer 801 to form BF₃ 853. Similarly, WF₆ may react with Si in the reducing agent layer 801 to form SiF₆ (not shown). As such, a layer 802 including B, Si, H, and W is present.

Some H₂ may not fully react with WF₆ (or other W fluorides) that remain on the surface from the prior dose. As shown in FIG. 8D, WF₆ may partially react with H₂ to form intermediate 843a, whereby in FIG. 8E, intermediate 843a remains partially reacted. Film deposited using a fluorine-containing tungsten precursor and hydrogen has a lower resistivity than a film deposited using a borane, silane, or germane. As discussed below, the bulk tungsten films deposited as described herein have low resistivity associated with H₂ reduction.

The stoichiometry of WF₆ may use at least three H₂ molecules to react with one molecule of WF₆. It is possible that WF₆ partially reacts with molecules of H₂ but rather than forming tungsten, an intermediate is formed. For example, this may occur if there is not enough H₂ in its vicinity to react with WF₆ based on stoichiometric principles (e.g., three H₂ molecules are used to react with one molecule of WF₆) thereby leaving an intermediate 843a on the surface of the substrate.

FIG. 8F provides an example schematic of the substrate when the chamber is purged. Note that compound 843c of FIG. 4F may be an intermediate formed but not completely reacted, while some tungsten 890 is present. Each cycle may thereby forms a sub-monolayer of tungsten on the substrate.

As an example, FIG. 8G shows an illustration where H₂ 811c in gas phase is introduced to the substrate with the deposited tungsten 890 and the partially reacted intermediate 843d thereon. At this stage, all of the B or B and Si in the reducing agent layer has been converted, leaving a W film 803. Note that as shown in FIG. 8G, the H₂ introduced may now fully react with the intermediate 443d on the substrate such that, as shown in FIG. 8H, the reacted compound 843d leaves behind deposited tungsten 890b and 890c, and byproducts HF 851c and 851d are formed in gas phase. Some H₂ 811c may remain in gas phase, while some H₂ 813c may remain on the tungsten layer 890a.

In FIG. 8I, the chamber is purged leaving behind deposited tungsten 490a, 490b, and 490c, and some H₂ 413c. In FIG. 8J, WF₆ is again introduced in a dose such that molecules 831c and 823c may then adsorb and/or react with H₂ and the substrate. WF₆ dose, the chamber may again be purged and cycles may be repeated again until the desired thickness of tungsten is deposited.

### EXPERIMENTAL

Tungsten bulk layers were deposited on SiOx/TiN using the following processes:
Process A: Deposition of 2-3 nm tungsten nucleation layer on TiN by multiple cycles (4-7) sequential pulses of B₂H₆ and WF₆ (B₂H₆/Ar/WF₆/Ar) at 250° C. and 10 Torr. Deposition of tungsten bulk layer on tungsten nucleation layer by sequential pulses of H₂ and WF₆ (H₂/Ar/WF₆/Ar) at 300° C. and 10 Torr.
Process B: Deposition of tungsten bulk layer on TiN by one pulse of B₂H₆ followed by one pulse of SiH₄ followed by sequential pulses of H₂ and WF₆ (H₂/Ar/WF₆/Ar) at 300° C. and 10 Torr.

Resistivities at 174 Angstrom film deposited by process A (nucleation) and process B (nucleation free) were measured as 20.2 micro-Ohm-centimeters for the W film deposited by process A (including the nucleation layer) and 17.7 micro-Ohm-centimeters for the nucleation-less film deposited by process B. A resistivity of about 14 micro-Ohm-centimeters was achieved for a nucleation-free deposition using a B reducing agent layer.

Potential issues can arise due to the presence of boron in bulk tungsten films. For example, the presence of boron-10, an isotope of boron, causes integration issues, such as processing defects during chemical mechanical planarization (CMP), or soft error rate defects due to interaction of isotope boron-10 with thermal neutrons. Specifically, boron-10 reacts with chemicals during CMP to form soluble boric acid, which leads to edge erosion, plug pull out, and other defects. Another concern in using boron-containing reducing agents may be its effect on the type of tungsten that forms in the feature. Beta-tungsten has a metastable A15 cubic crystalline structure and exhibits higher resistivity than the stable body-centered cubic crystalline structure of alpha-tungsten. Boron-based nucleation layers may lead to the presence of higher resistivity beta-tungsten—rather than alpha tungsten—in tungsten films.

FIG. 7B shows the atomic concentrations of boron and fluorine as a function of depth in a SiOx/TiN/W stack for W films deposited with and without nucleation layers. Peak boron concentration for process B (labeled “Nuc+LFW”) was about 5E+21 atoms/cm³. Peak boron concentration for process A (labeled “Nucless”) was less than 2E+20 atoms/cm³—over a magnitude less than for process A. In some embodiments, the peak boron concentration is less than 1E+21 atoms/cm³, or less than 5E+20 atoms/cm³, or less than 2E+20 atoms/cm³ at the interface of the tungsten layer and the underlying layer.

No interface is observed in the tungsten bulk layer deposited without a nucleation layer. By contrast, a nucleation layer—bulk interface is typically observed for films deposited using a nucleation layer. The bulk tungsten is alpha-tungsten.

Reducing agent layer formation: Results in the below table show the effect of diborane on the decomposition of silane in reducing agent layer formation on an oxide. Formation of the reducing agent layer was performed at 300° C. and 10 Torr using various mixtures of SiH₄ and B₂H₆ on blanket SiO₂. The balance of the reducing agent gas is H₂ and N₂ carrier gases in each case.

| % SiH₄ | % B₂H₆ | SiH₄ | B₂H₆ | | | % Si | % B | | SiH₄ | B₂H₆ |
|---|---|---|---|---|---|---|---|---|---|---|
| in | in | Exposure | Exposure | SiH₄:B₂H₆ | Dep Rate | in | in | | Sticking | Sticking |
| Dose | Dose | Torr-s | Torr-s | ratio | Å/cycle | layer | layer | S:B | Coef | Coef |
| 50% | 0 | 25 | 0 | ∞ | <5.0 | 100% | 0% | ∞ | 3.7E−7 | N/A |
| | | | | | discontinuous | | | | | |
| 45% | 0.25% | 22.5 | 0.125 | 180 | 17.1 | 76% | 24% | 3 | 2.4E−6 | 1.3E−5 |
| 25% | 1.25% | 12.5 | 0.625 | 20 | 18.0 | 40% | 60% | 0.7 | 1.7E−6 | 2.5E−5 |
| 5% | 2.25% | 2.5 | 1.125 | 2 | 9.4 | 16% | 84% | 0.2 | 1.3E−6 | 3.4E−5 |
| 0% | 2.50% | 0 | 1.250 | 0 | 6.0 | 0% | 100% | 0 | N/A | 1.1E−5 |

The above results show that a small amount of diborane greatly alters the silane decomposition. For example, the silane sticking coefficient is increased almost sevenfold by the addition of just 0.25% diborane. Co-flowing silane also increases the diborane coefficient by greater than twofold. Electron energy loss spectroscopy (EELS) analysis shows that the % B in the reducing agent layer is high relative to the % B₂H₆ in the reducing agent gas.

Grain size and orientation of tungsten was measured for different conditions of thermally decomposing diborane to form the boron layer.

| | | | B2H6 | | | |
|---|---|---|---|---|---|---|
| | Soak | Soak | dose | H2 | | Average |
| | Temperature | Pressure | time | flow | Texture | Crystallite |
| Process | (C.) | (T) | (s) | (sccm) | from XRD | size (nm) |
| A | 250 | 20 | 30 | 0 | 200-84.5% | 18.7 ± 3.0 |
| B | 250 | 20 | 30 | 5000 | 200-81.9% | 21.9 ± 3.7 |
| C | 250 | 20 | 120 | 0 | Random- | 19.9 ± 4.0 |
| | | | | | 68.8% | |
| D | 250 | 20 | 120 | 5000 | 200-83.9% | 15.8 ± 7.3 |
| E | 250 | 50 | 30 | 5000 | 200-88.4% | 17.3 ± 3.7 |
| F | 250 | 50 | 120 | 0 | Random- | 23.9 ± 3.9 |
| | | | | | 82.1% | |
| G | 250 | 50 | 120 | 5000 | 200-79.2% | 16.9 ± 4.2 |
| H | 275 | 35 | 66.5 | 2500 | 200-84.6% | 16.9 ± 4.1 |
| I | 300 | 20 | 15 | 0 | 200-75% | 12.0 ± 3.8 |
| J | 300 | 50 | 90 | 0 | Random- | 23.4 ± 3.3 |
| | | | | | 76.7% | |
| K | 300 | 50 | 90 | 5000 | Random- | 21.4 ± 3.4 |
| | | | | | 71.9% | |

The results demonstrate that a higher B content results in larger grain size and a more random grain orientation. They further demonstrate that grain orientation and/or size may be tuned by 1) adjusting H₂ (compare A and B; C and D; F and G; J and K) with lower H₂ generally resulting in larger and more random orientation; 2) adjusting diborane dose time (compare A and C; B and D; E and G); and 3) adjusting pressure (compare B and E; C and F; D and G).

In some embodiments, random orientation may not be avoided as it leads to high tensile stress. The grain size may be larger with random orientation, which reduces resistivity.

### Apparatus

Any suitable chamber may be used to implement the disclosed embodiments. Example deposition apparatuses include various systems, e.g., ALTUS® and ALTUS® Max, available from Lam Research Corp., of Fremont, California, or any of a variety of other commercially available processing systems. In some embodiments, deposition of a reducing agent layer may be performed at a first station that is one of two, five, or even more deposition stations positioned within a single deposition chamber. Thus, for example, silane (SiH₄) and diborane (B₂H₆) may be introduced to the surface of the semiconductor substrate, at the first station, using an individual gas supply system that creates a localized atmosphere at the substrate surface to form a reducing agent layer. Another station may be used for tungsten conversion of the reducing agent layer. In the same or other embodiments, two or more stations may be used to fill the features with bulk tungsten in parallel processing.

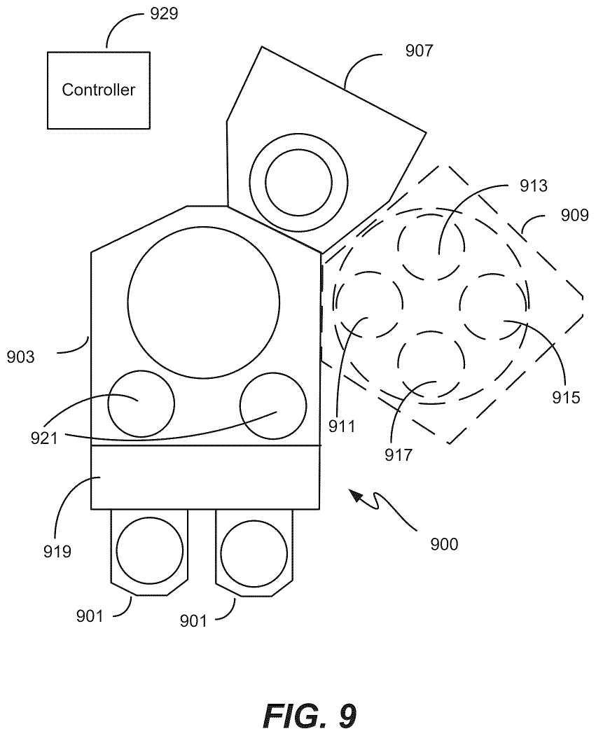

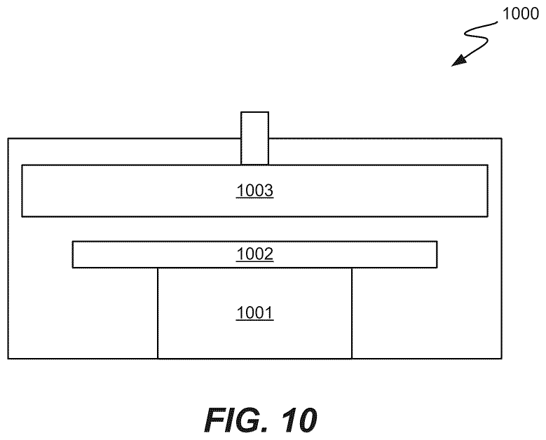

FIG. 9 is a block diagram of a processing system suitable for conducting deposition processes in accordance with embodiments. The system 900 includes a transfer module 903. The transfer module 903 provides a clean, pressurized environment to minimize risk of contamination of substrates being processed as they are moved between various reactor modules. Mounted on the transfer module 903 is a multi-station reactor 909. Multi-station reactor 909 may also be used to perform reducing agent layer deposition, tungsten conversion, and subsequent CVD in some embodiments. Reactor 909 may include multiple stations 911, 913, 915, and 917 that may sequentially perform operations in accordance with disclosed embodiments. For example, reactor 909 could be configured such that station 911 performs a first operation using a reducing agent and stations 913, 915, and 917 perform operations pulsing WF₆ and H₂. Each station may include a heated pedestal or substrate support for independent temperature control, one or more gas inlets or showerhead or dispersion plate. An example of a deposition station 1000 is depicted in FIG. 10, including substrate support 1002 and showerhead 1003. A heater may be provided in pedestal portion 1001.

Also mounted on the transfer module 903 may be one or more single or multi-station modules 907 capable of performing plasma or chemical (non-plasma) pre-cleans. The module may also be used for various treatments to, for example, prepare a substrate for a deposition process. The system 900 also includes one or more wafer source modules 901, where wafers are stored before and after processing. An atmospheric robot (not shown) in the atmospheric transfer chamber 919 may first remove wafers from the source modules 901 to loadlocks 921. A wafer transfer device (generally a robot arm unit) in the transfer module 903 moves the wafers from loadlocks 921 to and among the modules mounted on the transfer module 903.

In various embodiments, a system controller 929 is employed to control process conditions during deposition. The controller 929 will typically include one or more memory devices and one or more processors. A processor may include a CPU or computer, analog and/or digital input/output connections, stepper motor controller boards, etc.

The controller 929 may control all of the activities of the deposition apparatus. The system controller 929 executes system control software, including sets of instructions for controlling the timing, mixture of gases, chamber pressure, chamber temperature, wafer temperature, wafer chuck or pedestal position, and other parameters of a particular process. Other computer programs stored on memory devices associated with the controller 929 may be employed in some embodiments.

Typically there will be a user interface associated with the controller 929. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface.

Signals for monitoring the process may be provided by analog and/or digital input connections of the system controller 929. The signals for controlling the process are output on the analog and digital output connections of the deposition apparatus 900.

The system software may be designed or configured in many different ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a controller 929 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 929, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 929, in some implementations, may be a part of or coupled to a computer that is integrated with, coupled to the system, otherwise networked to the system, or a combination thereof. For example, the controller 929 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller 929 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

In the description above and in the claims, numerical ranges are inclusive of the end points of the range. For example, “between about 10 and 50 Angstroms thick” includes 10 Angstroms and 50 Angstroms. Similarly, ranges represented by a dash are inclusive of the end points of the ranges.

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments. It will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method comprising:
depositing an elemental tungsten bulk layer without depositing a tungsten nucleation layer on a surface of a substrate by:
forming a layer comprising elemental boron (B) on the surface; and
after forming the layer, performing multiple cycles of exposing the substrate to alternating pulses of a tungsten fluoride compound and hydrogen (H₂) to thereby form an elemental tungsten bulk layer on the surface.

2. The method of claim 1, wherein the B content at the interface of the elemental tungsten bulk layer and the surface is no more than 10²¹ atoms/cm³.

3. The method of claim 1, wherein the B content at the interface of the elemental tungsten bulk layer and the surface is no more than 5×10²⁰ atoms/cm³.

4. The method of claim 1, wherein the B content at the interface of the elemental tungsten bulk layer and the surface is no more than 2×10²⁰ atoms/cm³.

5. The method of claim 1, wherein the layer comprising elemental boron is between 10and 50 Angstroms thick.

6. The method of claim 1, wherein the layer comprising elemental boron is less than 30Angstroms thick.

7. The method of claim 1, wherein the layer comprising elemental boron consists essentially of boron.

8. The method of claim 1, wherein the layer comprising elemental boron further comprises silicon.

9. The method of claim 1, wherein the surface is a nitride surface.

10. The method of claim 1, wherein the surface is a titanium nitride surface.
